(19) United States
(12) Patent Application Publication
(10) Pub. No.: US 2026/0173722 A1
(43) Pub. Date: Jun. 18, 2026

(54) Display Apparatus

(71) Applicant: LG Display Co., Ltd., Seoul (KR)

(72) Inventors: JiHun Song, Paju-si (KR); Dohong Kim, Paju-si (KR); Hoiyong Kwon, Paju-si (KR)

(21) Appl. No.: 19/272,528

(22) Filed: Jul. 17, 2025

(30) Foreign Application Priority Data
Dec. 18, 2024 (KR) 10-2024-0190329

(51) Int. Cl. H10K 59/80

(52) U.S. Cl. CPC H10K 59/873

(57) ABSTRACT

A display apparatus comprising: a substrate having a display area in which a plurality of pixels having a plurality of sub-pixels are arranged and a non-display area around the display area; and an organic light-emitting layer provided on the substrate and each of the plurality of sub-pixels has the organic light-emitting layer, the organic light-emitting layer is arranged to extend from the display area to an end of the substrate, the substrate includes an undercut portion in which the organic light-emitting layer is disconnected, and the undercut portion is arranged in the non-display area to surround the display area.

### CROSS-REFERENCE TO RELATED APPLICATION

This application claims the benefit of the Republic of Korea Patent Application No. 10-2024-0190329 filed on Dec. 18, 2024, which is hereby incorporated by reference in its entirety.

### BACKGROUND

### Field of Technology

The present disclosure relates to a display apparatus.

### Discussion of the Related Art

Since an organic light emitting display apparatus has a high response speed and low power consumption and self-emits light without requiring a separate light source unlike a liquid crystal display apparatus, there is no problem in a viewing angle and thus the organic light emitting display apparatus has received attention as a next-generation flat panel display apparatus.

Such a display apparatus displays an image through light emission from a light-emitting layer interposed between a pixel electrode and an opposing electrode.

Meanwhile, display apparatuses are produced in models of various sizes because they have diverse application fields and uses. In order to manufacture display apparatuses of various sizes, light-emitting layers must be formed using masks of various sizes. Therefore, in order to manufacture display apparatuses of various sizes, masks (or EL masks) of various sizes are required, which causes problems of high manufacturing costs and increased production energy.

### SUMMARY

An embodiment of the present disclosure is directed to providing a display apparatus whose manufacturing cost can be reduced even when manufactured in various sizes.

Further, an embodiment of the present disclosure is directed to providing a display apparatus whose production energy can be reduced.

Further, an embodiment of the present disclosure is directed to providing a display apparatus in which moisture penetration can be reduced or prevented even when manufactured in various sizes.

Further, an embodiment of the present disclosure is directed to providing a display apparatus in which dark spot defects in a display area can be improved or prevented.

Further, an embodiment of the present disclosure is directed to providing a display apparatus in which cathode contact failure in a common power shorting bar can be prevented.

The problems to be solved by the examples of the present disclosure are not limited to those mentioned above, and other problems not mentioned will be apparent to one of ordinary skill in the art to which the technical spirits of the present disclosure belong from the following description.

A display apparatus according to an embodiment of the present disclosure comprises: a substrate having a display area in which a plurality of pixels having a plurality of sub-pixels are arranged and a non-display area around the display area; and an organic light-emitting layer provided on the substrate and each of the plurality of sub-pixels has the organic light-emitting layer, the organic light-emitting layer is arranged to extend from the display area to an end of the substrate, the substrate includes an undercut portion in which the organic light-emitting layer is disconnected, and the undercut portion is arranged in the non-display area to surround the display area.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain the principle of the disclosure. In the drawings:

FIG. 1 is a schematic plan view of a display apparatus according to one embodiment of the present disclosure.

FIG. 2 is a schematic cross-sectional view of the line I-I′ shown in FIG. 1 according to one embodiment of the present disclosure.

FIG. 3 is a plan view schematically illustrating an undercut formation area and a cathode formation area in a substrate of a display apparatus according to one embodiment of the present disclosure.

FIG. 4 is a schematic cross-sectional view of the line II-II′ shown in FIG. 3 according to one embodiment of the present disclosure.

FIG. 5 is a schematic cross-sectional view of the line III-III′ shown in FIG. 3 according to one embodiment of the present disclosure.

FIG. 6 is a schematic cross-sectional view of the line IV-IV′ shown in FIG. 3 according to one embodiment of the present disclosure.

FIG. 7 is a schematic cross-sectional view of the line V-V′ shown in FIG. 3 according to one embodiment of the present disclosure.

### DETAILED DESCRIPTION

Reference will now be made in detail to the embodiments of the present disclosure, examples of which are illustrated in the accompanying drawings. Wherever possible, the same reference numbers will be used throughout the drawings to refer to the same or like parts.

Advantages and features of the present disclosure, and implementation methods thereof will be clarified through following embodiments described with reference to the accompanying drawings.

The present disclosure may, however, be embodied in different forms and should not be construed as limited to the embodiments set forth herein. Rather, these embodiments are provided so that this disclosure will be thorough and complete, and will fully convey the scope of the present disclosure to those skilled in the art. Further, the present disclosure is defined by the scope of the claims.

A shape, a size, a ratio, an angle, and a number disclosed in the drawings for describing embodiments of the present disclosure are merely one example, and thus, the present disclosure is not limited to the illustrated details.

Like reference numerals refer to like elements throughout. In the following description, when the detailed description of the relevant known function or configuration is determined to unnecessarily obscure the important point of the present disclosure, the detailed description will be omitted.

In a case where ‘comprise’, ‘have’, and ‘include’ described in the present disclosure are used, another part may be added unless ‘only˜’ is used. The terms of a singular form may include plural forms unless referred to the contrary.

In construing an element, the element is construed as including an error range although there is no explicit description.

In describing a position relationship, for example, when a position relation between two parts is described as ‘on˜’, ‘over˜’, ‘under˜’, and ‘next˜’, one or more other parts may be disposed between the two parts unless ‘just’ or ‘direct’ is used.

In describing a temporal relationship, for example, when the temporal order is described as “after,” “subsequent,” “next,” and “before,” a case which is not continuous may be included, unless “just” or “direct” is used.

It will be understood that, although the terms “first,” “second,” etc. may be used herein to describe various elements, these elements should not be limited by these terms. These terms are only used to distinguish one element from another. For example, a first element could be termed a second element, and, similarly, a second element could be termed a first element, without departing from the scope of the present disclosure.

“X-axis direction”, “Y-axis direction” and “Z-axis direction” should not be construed by a geometric relation only of a mutual vertical relation and may have broader directionality within the range that elements of the present disclosure may act functionally.

The term “at least one” should be understood as including any and all combinations of one or more of the associated listed items. For example, the meaning of “at least one of a first item, a second item and a third item” denotes the combination of all items proposed from two or more of the first item, the second item and the third item as well as the first item, the second item or the third item.

Features of various embodiments of the present disclosure may be partially or overall coupled to or combined with each other and may be variously inter-operated with each other and driven technically as those skilled in the art can sufficiently understand. The embodiments of the present disclosure may be carried out independently from each other or may be carried out together in co-dependent relationship.

Hereinafter, the preferred embodiments of the present disclosure will be described in detail with reference to the accompanying drawings.

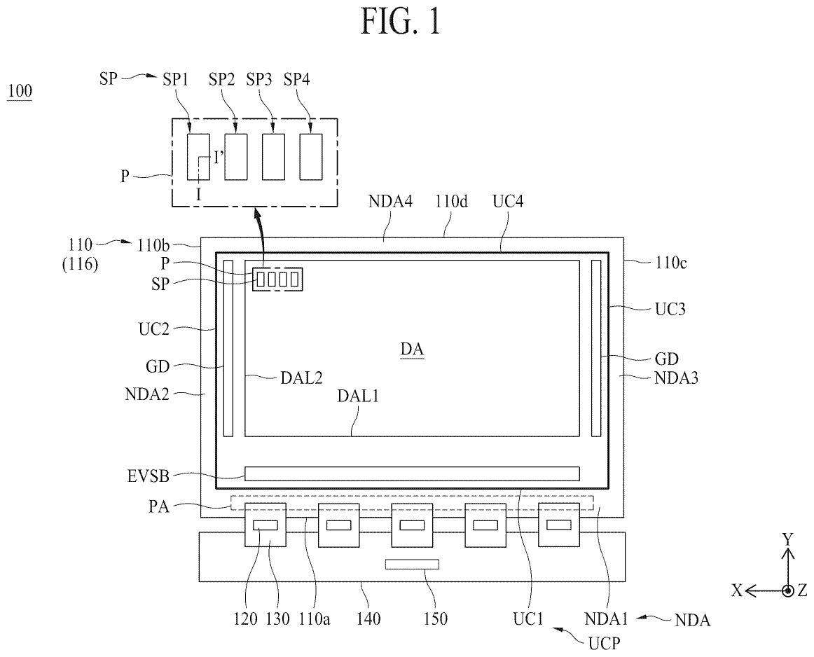

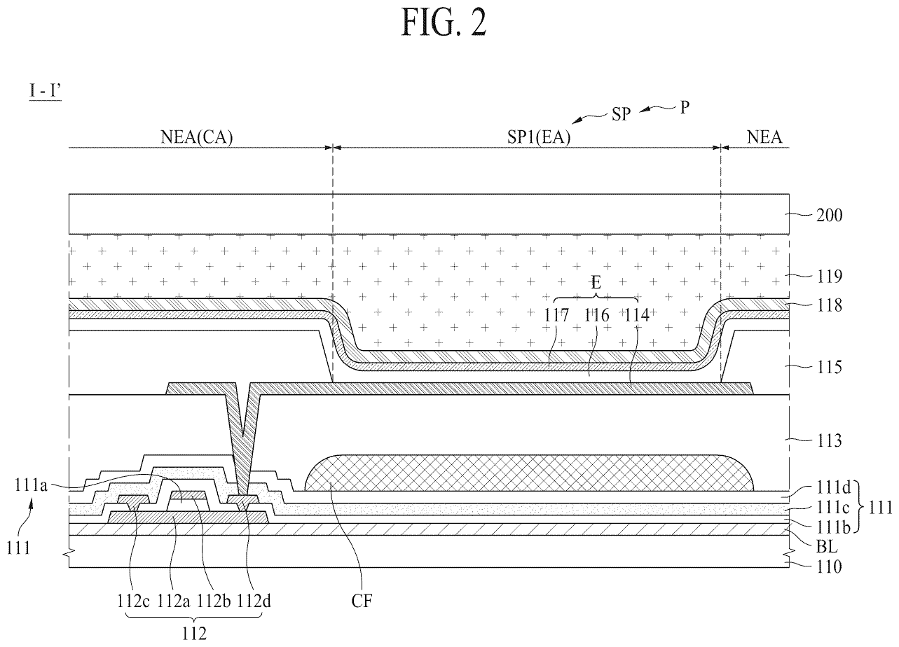

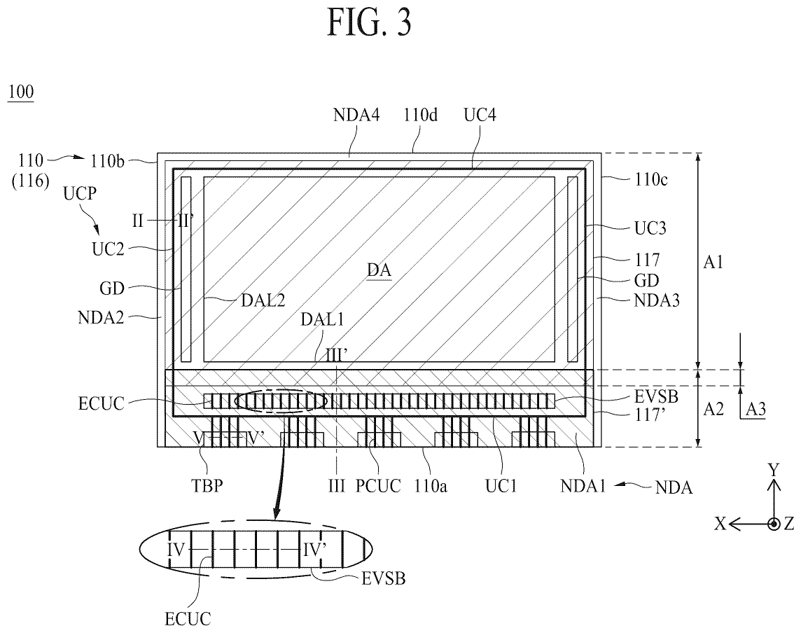

FIG. 1 is a schematic plan view of a display apparatus according to one embodiment of the present disclosure, FIG. 2 is a schematic cross-sectional view of the line I-I′ shown in FIG. 1 according to one embodiment of the present disclosure, and FIG. 3 is a plan view schematically illustrating an undercut formation area and a cathode formation area in a substrate of a display apparatus according to one embodiment of the present disclosure.

Hereinafter, a first direction (Y-axis direction) represents a vertical direction based on FIG. 1, a second direction (X-axis direction) represents a horizontal direction based on FIG. 1, and a third direction (Z-axis direction) represents a thickness direction of a display apparatus 100. For example, the first direction (Y-axis direction) may be a direction parallel to a data wiring (not shown), the second direction (X-axis direction) may be a direction parallel to a gate wiring (not shown).

Referring to FIG. 1, a display apparatus 100 according to one embodiment of the present disclosure may include a display panel having a gate driver GD. The display panel may include a substrate 110 and an opposing substrate 200 (shown in FIG. 2) bonded to each other.

The substrate 110 according to one example may include a display area DA in which a plurality of pixels P having a plurality of subpixels SP are arranged, and a non-display area NDA around the display area DA.

A display apparatus 100 according to one embodiment of the present disclosure may further include an organic light-emitting layer 116 provided on the substrate 110 and each of the plurality of subpixels SP. The organic light-emitting layer 116 may be arranged to extend from the display area DA to an end of the substrate 110.

For example, as shown in FIG. 1, the organic light-emitting layer 116 may be arranged to extend from the display area DA to an end 110a (or a first end 110a) of the substrate 110 in a first non-display area NDA1 of the non-display area NDA. Additionally, the organic light-emitting layer 116 may be arranged to extend from the display area DA to an end 110b (or a second end 110b) of the substrate 110 in a second non-display area NDA2 of the non-display area NDA. Additionally, the organic light-emitting layer 116 may be arranged to extend from the display area DA to an end 110c (or a third end 110c) of the substrate 110 in a third non-display area NDA3 of the non-display area NDA. In addition, the organic light-emitting layer 116 may be arranged to extend from the display area DA to an end 110d (or a fourth end 110d) of the substrate 110 in a fourth non-display area NDA4 of the non-display area NDA. Accordingly, the organic light-emitting layer 116 may be arranged in both the display area DA and the non-display area NDA.

As a result, the display apparatus 100 according to one embodiment of the present disclosure may have a structural feature in which the organic light-emitting layer 116 is arranged to extend from the display area DA to the end of the substrate 110.

In the case of a general display apparatus, since a light-emitting layer must be formed using masks (or EL masks) of various sizes to manufacture display apparatuses of various sizes, masks (or EL masks) of various sizes are required. Accordingly, the general display apparatus has the problem of high manufacturing costs and increased production energy.

However, since the display apparatus 100 according to one embodiment of the present disclosure is provided so that the organic light-emitting layer 116 extends from the display area DA to the end of the substrate 110, masks (or EL masks) of various sizes are not required, so that even if it is manufactured in various sizes, the manufacturing cost can be reduced.

Meanwhile, as described above, in the case of the general display apparatus, the light-emitting layer must be formed using masks (or EL masks) of various sizes. The mask (or opening of the mask) of the general display apparatus is provided to be smaller than a size of the substrate so that the light-emitting layer is not placed at the end of the substrate. When the light-emitting layer is placed at the end of the substrate, the light-emitting layer is exposed to an outside at the end of the substrate, so defects may occur due to moisture and oxygen permeation (or penetration). Therefore, in the case of the general display apparatus, a mask (or EL mask) for forming a light-emitting layer is absolutely necessary, and a size of the mask (or the opening of the mask) is provided to be smaller than the size of the substrate.

In contrast, the display apparatus 100 according to one embodiment of the present disclosure may be provided such that the substrate 110 includes an undercut portion UCP. According to one example, the undercut portion UCP is for disconnecting the organic light-emitting layer 116. As shown in FIG. 1, the undercut portion UCP may be arranged in the non-display area NDA to surround the display area DA. The undercut portion UCP may include a first undercut UC1, a second undercut UC2, a third undercut UC3, and a fourth undercut UC4.

Therefore, in the display apparatus 100 according to one embodiment of the present disclosure, the undercut portion UCP is arranged to surround the display area DA, so that even if the organic light-emitting layer 116 is arranged to extend from the display area DA to the end of the substrate 110, moisture and oxygen permeation (or penetration) through the organic light-emitting layer 116 can be prevented by the undercut portion UCP. That is, in the display apparatus 100 according to one embodiment of the present disclosure, moisture permeation can be reduced or prevented by arranging the undercut portion UCP in which the organic light-emitting layer 116 is disconnected around the display area DA. Therefore, since the display apparatus 100 according to one embodiment of the present disclosure does not require a mask (or EL mask) for forming the organic light-emitting layer 116, the manufacturing cost can be reduced even if it is manufactured in various sizes.

In addition, since the display apparatus 100 according to one embodiment of the present disclosure can be manufactured in various sizes without masks (or EL masks) of various sizes, a process can be optimized compared to a general display apparatus manufactured using masks (or EL masks) of various sizes, and thus production energy can be reduced.

Referring to FIG. 1, a display apparatus 100 according to one embodiment of the present disclosure may include a source drive integrated circuit (hereinafter referred to as “IC”) 120, a flexible film 130, a circuit board 140, and a timing control portion 150.

The substrate 110 may include a thin film transistor, and may be a transistor array substrate, a lower substrate, a base substrate, or a first substrate. The substrate 110 may be a transparent glass substrate or a transparent plastic substrate.

The opposing substrate 200 may be bonded to the substrate 110 via an adhesive member. For example, the opposing substrate 200 has a smaller size than the substrate 110 and can be bonded to a remaining portion except for a pad portion PA of the substrate 110. The opposing substrate 200 may be an upper substrate, a second substrate, or an encapsulation substrate.

The gate driver GD supplies gate signals to the gate lines in accordance with the gate control signal input from the timing control portion 150. When the source drive IC 120 is manufactured as a driving chip, the source drive IC 120 may be packaged in the flexible film 130 in a chip on film COF method or a chip on plastic COP method.

Pads, such as data pads, may be formed in the non-display area of the display panel. Lines connecting the pads with the source drive IC 120 and lines connecting the pads with lines of the circuit board 140 may be formed in the flexible film 130. The flexible film 130 may be attached onto the pads by using an anisotropic conducting film, whereby the pads may be connected with the lines of the flexible film 130.

Referring to FIG. 1, the substrate 110 according to one example may include a display area DA and a non-display area NDA.

The display area DA is an area where an image is displayed, and may be a pixel array area, an active area, a pixel array unit, a display unit, or a screen. For example, the display area DA may be disposed at a central portion of the display panel.

The display area DA according to one example may include gate wirings, data wirings, pixel power wirings, and a plurality of pixels P. Each of the plurality of pixels P may include a plurality of sub-pixels SP that may be defined by gate wirings and data wirings. Each of the plurality of sub-pixels SP may be defined as the smallest unit area where actual light is emitted.

According to one example, at least four subpixels SP arranged adjacently and configured to emit different colors among a plurality of subpixels SP constitute one unit pixel P. The one unit pixel may include, but is not limited to, a red subpixel, a green subpixel, a blue subpixel, and a white subpixel.

Each of the plurality of subpixels SP may include a thin film transistor and an organic light-emitting element connected to the thin film transistor. The subpixel may include an organic light-emitting layer (or light-emitting layer) interposed between a first electrode and a second electrode.

The organic light-emitting layer arranged in each of the plurality of subpixels SP can individually emit different color light or commonly emit white light. For example, when the organic light-emitting layer of each of the plurality of sub-pixels SP commonly emits white light, each of the red sub-pixel, the green sub-pixel, and the blue sub-pixel may include a color filter CF (or wavelength conversion member CF) that converts the white light into light of a different color. In this case, the white subpixel according to one example may not have a color filter. The color filter CF according to one example may include a red color filter, a green color filter, and a blue color filter.

In a display apparatus 100 according to one embodiment of the present disclosure, an area provided with the red color filter may be a red subpixel SP1, an area provided with the green color filter may be a green subpixel SP3, an area provided with the blue color filter may be a blue subpixel SP4, and an area without the color filter may be a white subpixel SP2. In the present disclosure, the red subpixel SP1 may be represented as a first subpixel equipped to emit red light, the green subpixel SP3 may be represented as a third subpixel equipped to emit blue light, the blue subpixel SP4 may be represented as a fourth subpixel equipped to emit green light, and the white subpixel SP2 may be represented as a second subpixel equipped to emit white light.

Each of the subpixels SP supplies a predetermined current to the organic light emitting element in accordance with a data voltage of the data wiring when a gate signal is input from the gate line by using the thin film transistor. For this reason, the light emitting layer of each of the subpixels may emit light with a predetermined brightness in accordance with the predetermined current.

As shown in FIG. 2, the display area DA may include a light emission area EA and a non-light emission area NEA. The light emission area EA is the area where light is emitted by the organic light-emitting element layer E. The non-light emission area NEA is the area that does not transmit most of the light incident from the outside.

For example, the non-light emission area NEA may be an area excluding the light emission area EA where light is emitted. In one example, the non-light emission area NEA may include a circuit area CA. The circuit area CA may include a thin film transistor 112 for driving the organic light emitting element layer E. Additionally, in the non-light emission area NEA, the plurality of pixels P and a plurality of lines for driving each of the plurality of pixels P can be disposed. The plurality of lines, according to one example, can include a plurality of first signal lines and a plurality of second signal lines.

The plurality of first signal lines may be extended in the second direction (X-axis direction). Each of the plurality of first signal lines may include at least one gate line (or scan line). The gate line according to one example can be electrically connected to the gate driver GD.

The plurality of second signal lines can extend in the first direction (Y-axis direction). The plurality of second signal lines can intersect with the plurality of first signal lines. Each of the plurality of second signal lines may include a pixel power line, a plurality of data lines, and a reference line. The plurality of data lines can include a first data line for driving the first sub-pixel SP1, a second data line for driving the second sub-pixel SP2, a third data line for driving the third sub-pixel SP3, and a fourth data line for driving the fourth sub-pixel SP4.

Referring back to FIG. 1, the non-display area NDA is an area on which an image is not displayed, and may be a peripheral circuit area, a signal supply area, an inactive area or a bezel area. The non-display area NDA may be configured to be in the vicinity of the display area DA. That is, the non-display area NDA may be disposed to surround the display area DA. That is, the non-display area NDA can be arranged to surround the display area DA. According to one example, the non-display area NDA can include a first non-display area NDA1, a second non-display area NDA2, a third non-display area NDA3, and a fourth non-display area NDA4.

The display apparatus 100 according to one embodiment of the present disclosure can include a pad portion PA disposed in the non-display area NDA. The pad portion PA can be for driving the plurality of pixels P. For example, the pad portion PA can supply power and/or signals for the plurality of pixels P disposed in the display area DA to output images. According to one example, the pad portion PA may be placed in the first non-display area NDA1 below the display area DA based on FIG. 1. As shown in FIG. 1, the first non-display area NDA1 may be adjacent to a first side DAL1 of the display area DA. The first side DAL1 of the display area DA may be a side that is parallel to the second direction (X-axis direction) in the display area DA. The first undercut UC1 including the undercut portion UCP may be formed in the first non-display area NDA1.

The gate driver GD supplies gate signals to the gate lines in accordance with the gate control signal input from the timing control portion 150. The gate driver GD may be formed on one side of the display area DA of the display panel or on the non-display area NDA outside both sides of the display area DA in a gate driver in panel GIP method as shown in FIG. 1.

The plurality of gate drivers GD may be separately disposed on a left side of the display area DA, that is, the second non-display area and a right side of the display area DA, that is, the third non-display area. According to one example, the plurality of gate drivers GD may be connected to the plurality of pixels P and the plurality of first signal lines for supplying signals to the plurality of pixels P. The plurality of first signal lines may include at least one signal line for supplying a signal for driving the pixel P.

Meanwhile, the second non-display area NDA2 can be connected to the first non-display area NDA1. Additionally, the third non-display area NDA3 can also be connected to the first non-display area NDA1, and the fourth non-display area NDA4 can be connected to the first non-display area NDA1 via the second non-display area NDA2 and the third non-display area NDA3. Accordingly, the first to fourth non-display areas NDA1, NDA2, NDA3, NDA4 may be provided to surround the display area DA.

As shown in FIG. 1, the second non-display area NDA2 may be adjacent to a second side DAL2 of the display area DA. The second side DAL2 of the display area DA may be a side that is parallel to the first direction (Y-axis direction) in the display area DA. The second undercut UC2 including the undercut portion UCP may be formed in the second non-display area NDA2.

The third non-display area NDA3 may be provided spaced apart from the second non-display area NDA2 with the display area DA therebetween. The third undercut UC3 including the undercut portion UCP may be formed in the third non-display area NDA3.

The plurality of second signal lines may extend in the first direction (Y-axis direction). The plurality of second signal lines may include a pixel power line and at least one data line to supply a data voltage to the pixel P. Each of the plurality of second signal lines may be connected to at least one of a plurality of pads, a pixel power shorting bar, and a common power shorting bar EVSB. The pixel power shorting bar and the common power shorting bar EVSB can be arranged in the fourth non-display area NDA4 facing the pad portion PA based on the display area DA. According to one example, the fourth non-display area NDA4 may be provided spaced apart from the first non-display area NDA1 with the display area DA therebetween. The fourth undercut UC4 including the undercut portion UCP may be formed in the fourth non-display area NDA4.

As shown in FIG. 1, the first undercut UC1, the second undercut UC2, the third undercut UC3, and the fourth undercut UC4 can all be connected. Accordingly, the display apparatus 100 according to one embodiment of the present disclosure can have improved reliability by preventing moisture penetration through the organic light-emitting layer 116 by arranging the first to fourth undercuts UC1, UC2, UC3, UC4 to surround the display area DA in the non-display area NDA.

The pixels P are provided to overlap at least one of the first signal line or the second signal line and emit predetermined light to display an image. The light emission area EA may correspond to an area, which emits light, in the pixel P.

Referring to FIG. 2, the non-light emission area NEA may refer to an area that is provided in the display area DA and does not emit light and may be expressed as a dead zone because it does not emit light. The dead zone according to one example may be an area in which a black matrix and/or a bank is provided, but is not limited thereto, and may refer to an area in which light is not emitted.

Hereinafter, with reference to FIGS. 2 and 3, the structure of each of the plurality of sub-pixels SP will be described in detail.

The display apparatus 100 according to one embodiment of the present disclosure can include a buffer layer BL, a plurality of inorganic films 111, a thin film transistor 112, a color filter CF, a planarization layer 113, a pixel electrode 114, a bank 115, an organic light emitting layer 116, a first cathode electrode 117, a second cathode electrode 117′ (shown in FIG. 3), an encapsulation layer 118, and a filling layer 119.

Each of the subpixels SP according to one embodiment may include the plurality of inorganic films 111 provided on an upper surface of the buffer layer BL, including a gate insulating layer 111a, an interlayer insulating layer 111b, a first passivation layer 111c and a second passivation layer 111d.

Also, each of the subpixels SP may include a color filter CF provided on the plurality of inorganic films 111, a planarization layer 113 provided on the color filter CF. The pixel electrode 114 may be disposed on the planarization layer 113.

Each of the subpixels SP may further include a bank 115 covering one edge of the pixel electrode 114, an organic light-emitting layer 116 on the pixel electrode 114 and the bank 115, and a first cathode electrode 117 on the organic light-emitting layer 116. The encapsulation layer 118 may be placed on the first cathode electrode 117, the filling layer 119 can be placed on the encapsulation layer 118.

The plurality of inorganic films 111 can be provided between the substrate 110 and the organic light-emitting layer 116. The thin film transistor 112 for driving of subpixel SP may be arranged on the plurality of inorganic films 111. The plurality of inorganic films 111 may also be expressed in terms of a circuit element layer.

The buffer layer BL may be included in the plurality of inorganic films 111 together with the gate insulating layer 111a, the interlayer insulating layer 111b, the first passivation layer 111c, and the second passivation layer 111d. The pixel electrode 114, the organic light emitting layer 116 and the cathode electrode 117 may be included in a light emitting element layer E.

The buffer layer BL may be formed between the substrate 110 and the gate insulating layer 111a to protect the thin film transistor 112. The buffer layer BL may be disposed on the entire surface (or front surface) of the substrate 110. The buffer layer BL may serve to block diffusion of a material contained in the substrate 110 into a transistor layer during a high temperature process of a manufacturing process of the thin film transistor 112.

The thin film transistor 112 (or a drive transistor) according to one example may include an active layer 112a, a gate electrode 112b, a source electrode 112c, and a drain electrode 112d.

The active layer 112a may include a channel area, a drain area and a source area, which are formed in a thin film transistor area of a circuit area CA of the subpixel SP. The drain area and the source area may be spaced apart from each other with the channel area interposed therebetween.

The active layer 112a may be formed of a semiconductor material based on any one of amorphous silicon, polycrystalline silicon, oxide and organic material.

The gate insulating layer 111a may be formed on the channel area of the active layer 112a. As one example, the gate insulating layer 111a may be formed in an island shape only on the channel area of the active layer 112a or may be formed on the entire front surface of the substrate 110 or buffer layer BL including the active layer 112a.

The gate electrode 112b may be formed on the gate insulating layer 111a to overlap the channel area of the active layer 112a.

The interlayer insulating layer 111b can be formed to partially overlap the gate electrode 112b and the drain area and source area of the active layer 112a. The interlayer insulating layer 111b may be formed over the entire light emission area where light is emitted, as in FIG. 3, in the circuit area CA and the subpixel SP.

The source electrode 112c may be electrically connected to the source area of the active layer 112a through a source contact hole provided in the interlayer insulating layer overlapped with the source area of the active layer 112a.

The drain electrode 112d may be electrically connected to the drain area of the active layer 112a through a drain contact hole provided in the interlayer insulating layer overlapped with the drain area of the active layer 112a.

The drain electrode 112d and the source electrode 112c may be made of the same metal material. For example, each of the drain electrode 112d and the source electrode 112c may be made of a single metal layer, a single layer of an alloy or a multi-layer of two or more layers, which is the same as or different from that of the gate electrode 112b.

Additionally, the thin film transistor provided in the pixel area may have a characteristic in which the threshold voltage is shifted by light. To prevent this, the display panel or the substrate 110 may further include a light-shielding layer (not shown) provided under the active layer 112a of at least one of the thin film transistor 112, a first switching thin film transistor, and a second switching thin film transistor. The light-shielding layer is provided between the substrate 110 and the active layer 112a to block light incident on the active layer 112a through the substrate 110, thereby minimizing or at least reducing changes in the threshold voltage of the transistor caused by external light. In addition, the light shielding layer may be provided between the substrate 110 and the active layer 112a to prevent the thin film transistor from being visible to the user.

The first passivation layer 111c may be provided on the substrate 110 to cover the pixel area. The first passivation layer 111c covers a drain electrode 112d, a source electrode 112c and a gate electrode 112b of the thin film transistor 112, and the buffer layer BL.

The second passivation layer 111d may be provided on the substrate 110 to cover the first passivation layer 111c. The second passivation layer 111d may be partially disposed between the first passivation layer 111c and the color filter CF.

The color filter CF may be placed on the second passivation layer 111d. For example, the color filter CF may be placed between the plurality of inorganic films 111 and the planarization layer 113. The color filter CF may include a red color filter arranged in the red subpixel SP1, a green color filter arranged in the green subpixel SP3, and a blue color filter arranged in the blue subpixel SP4. Since the white subpixel SP2 is provided to emit white light, it may not include the color filter.

The planarization layer 113 may be provided on the substrate 110 to cover the second passivation layer 111d and the color filter CF. According to one example, the planarization layer 113 may be placed between the plurality of inorganic films 111 and the organic light-emitting layer 116. The planarization layer 113 may be formed in the entire circuit area CA in which the thin film transistor 112 is disposed and the entire light emission area EA. In addition, the planarization layer 113 may be formed in the other non-display area NDA except a pad area PA of the non-display area NDA and the entire display area DA. For example, the planarization layer 113 may include an extension portion (or an enlarged portion) extended or enlarged from the display area DA to the other non-display area NDA except the pad area PA. Therefore, the planarization layer 113 may have a size relatively wider than that of the display area DA.

The planarization layer 113 according to one example may be formed to have a relatively thick thickness, thereby providing a flat surface on the display area DA and the non-display area NDA. For example, the planarization layer 113 may be made of an organic material such as photo acryl, benzocyclobutene, polyimide and fluorine resin.

Meanwhile, an upper surface of the planarization layer 113 can be provided flat. Accordingly, the pixel electrode 114 on the planarization layer 113 can also be provided flat, and the organic light-emitting layer 116 and the first cathode electrode 117 formed thereon can also be provided in a flat form. Since the pixel electrode 114, the organic light-emitting layer 116, and the first cathode electrode 117, i.e., the organic light-emitting element layer E, are provided flatly in the light-emission area EA, a thicknesses of the pixel electrode 114, the organic light-emitting layer 116, and the first cathode electrode 117 can be formed uniformly within the light-emission area EA. Accordingly, the organic light-emitting layer 116 can emit light uniformly without deviation within the light-emission area EA.

The pixel electrode 114 may be formed on the planarization layer 113. The pixel electrode 114 may be connected to the drain electrode or source electrode of the thin film transistor through a contact hole penetrating the planarization layer 113, the second passivation layer 111d, and the first passivation layer 111c. An edge portions on both sides of the pixel electrode 114 may be covered by the bank 115. The pixel electrode 114 may be made of at least one of a transparent metal material or a semi-transmissive metal material.

Because the display apparatus 100 according to an embodiment of the present disclosure is configured as the bottom emission type, the pixel electrode 114 may be formed of a transparent conductive material (or TCO), such as indium tin oxide (ITO) or indium zinc oxide (IZO) capable of transmitting light, or a semi-transmissive conductive material such as magnesium (Mg), silver (Ag), or an alloy of Mg and Ag.

Meanwhile, the material constituting the pixel electrode 114 may include MoTi. The pixel electrode 114 may be a first electrode or an anode electrode.

The bank 115 may be an area, which does not emit light, and can be placed adjacent to the light emission area EA of each of the plurality of sub-pixels SP. For example, the bank 115 may be disposed in the non-light emission area NEA. The bank 115 may be formed to cover a portion where the edge of the pixel electrode 114. Accordingly, the bank 115 may prevent the pixel electrode 114 and the cathode electrode 117 in the edge of the pixel electrode 114. The exposed portion of the pixel electrode 114 that is not covered by the bank 115 may be included in the light emitting portion (or light emission area EA).

After the bank 115 is formed, an organic light emitting layer 116 may be formed to cover the pixel electrode 114 and the bank 115. Thus, the bank 115 may be partially provided between the pixel electrode 114 and the organic light emitting layer 116. The bank 115 can be expressed in terms of a pixel definition films. The bank 115 according to one example may comprise organic material and/or inorganic material.

The organic light emitting layer 116 may be formed on the pixel electrode 114 and the bank 115. The organic light emitting layer 116 can be placed under the first cathode electrode 117. According to one example, the organic light emitting layer 116 may be disposed in the light emission area EA and the non-light emission area NEA. The organic light emitting layer 116 may be provided between the pixel electrode 114 and the first cathode electrode 117. Thus, when a voltage is applied to each of the pixel electrode 114 and the first cathode electrode 117, an electric field is formed between the pixel electrode 114 and the first cathode electrode 117. Therefore, the organic light emitting layer 116 may emit light. The organic light emitting layer 116 may be formed of a plurality of subpixels SP and a common layer provided on the bank 115.

The organic light emitting layer 116 according to one embodiment may be provided to emit white light. The organic light emitting layer 116 may include a plurality of stacks which emit lights of different colors. For example, the organic light emitting layer 116 may include a first stack, a second stack, and a charge generating layer (CGL) provided between the first stack and the second stack. The light emitting layer may be provided to emit the white light, and thus, each of the plurality of subpixels SP may include a color filter CF suitable for a corresponding color.

The first stack may be provided on the pixel electrode 114 and may be implemented a structure where a hole injection layer (HIL), a hole transport layer (HTL), an emission layer (EML(B)), and an electron transport layer (ETL) are sequentially stacked.

The charge generating layer may supply an electric charge to the first stack and the second stack. The charge generating layer may include an N-type charge generating layer for supplying an electron to the first stack and a P-type charge generating layer for supplying a hole to the second stack. The N-type charge generating layer may include a metal material as a dopant.

The second stack may be provided on the first stack and may be implemented in a structure where a hole transport layer (HTL), a yellow-green (YG) emission layer (EML(YG)), and an electron injection layer (EIL) are sequentially stacked.

In the display apparatus 100 according to an embodiment of the present disclosure, because the organic light emitting layer 116 is provided as a common layer, the first stack, the charge generating layer, and the second stack may be arranged all over the plurality of subpixels SP. The organic light emitting layer 116, according to another example, may be provided in a three-stacked structure or a four-stacked structure, depending on the number of stacks stacked.

Meanwhile, in the display apparatus 100 according to one embodiment of the present disclosure, since the organic light-emitting layer 116 is disconnected by the undercut portion UCP around the display area DA, moisture penetration can be prevented even if the organic light-emitting layer 116 is arranged to extend from the display area DA to the end of the substrate 110.

The first cathode electrode 117 may be formed on the organic light-emitting layer 116. The first cathode electrode 117 may be overlapped (or arranged) in the non-display area NDA (or a part of the non-display area NDA) and the display area DA. In the display area DA, the first cathode electrode 117 may be arranged in the light-emission area EA and the non-light emission area NEA. That is, the first cathode electrode 117 may be provided to cover the entire display area DA. As a result, the first cathode electrode 117 may have a size that is larger than the display area DA and smaller than the substrate 110, so that it may be arranged in the non-display area NDA (or the part of the non-display area NDA) and the display area DA. The first cathode electrode 117 may be formed before the second cathode electrode 117′.

As described above, the first cathode electrode 117 can be arranged in the non-display area NDA (or the part of the non-display area NDA) and the entire display area DA. Therefore, in the display apparatus 100 according to one embodiment of the present disclosure, foreign substances that may occur during a process for forming the second cathode electrode 117′ can be prevented from being attached to the organic light-emitting layer 116 of the display area DA, so that the defect rate of the display apparatus can be reduced. That is, in the display apparatus 100 according to one embodiment of the present disclosure, the first cathode electrode 117 is formed before the second cathode electrode 117′ so as to cover the entire non-display area NDA (or the part of the non-display area NDA) and the display area DA, so that an influence of foreign substance deposition on the display area DA that may occur during the moving process for forming the second cathode electrode 117′ can be reduced.

The first cathode electrode 117 according to one example may include a metal material. The first cathode electrode 117 may reflect light emitted from the organic light-emitting layer 116 in the plurality of subpixels SP toward the lower surface of the substrate 110. Therefore, the display apparatus 100 according to an embodiment of the present disclosure may be implemented as a bottom emission display apparatus.

The display apparatus 100 according to one embodiment of the present disclosure is a bottom emission type and has to reflect light emitted from the light emitting layer 116 toward the substrate 110. Thus, the first cathode electrode 117 may be made of a metal material having high reflectance. According to one example, the first cathode electrode 117 may be formed of an opaque metal material. For example, the opaque metal material may be a metal material having high reflectance such as silver (Ag), aluminum (Al), a stacked structure (Ti/Al/Ti) of aluminum and titanium, a stacked structure (ITO/Al/ITO) of aluminum and ITO, an Ag alloy and a stacked structure (ITO/Ag alloy/ITO) of Ag alloy and ITO. The Ag alloy may be an alloy such as silver (Ag), palladium (Pd) and copper (Cu). The first cathode electrode 117 may be expressed as terms such as a second electrode, an opposing electrode and a reflective electrode.

The second cathode electrode 117′ may be disposed on the first cathode electrode 117. The second cathode electrode 117′ may be formed later than the first cathode electrode 117, and thus may be disposed on the first cathode electrode 117. Accordingly, the second cathode electrode 117′ may also be formed on the organic light-emitting layer 116. Referring to FIG. 3, the second cathode electrode 117′ may be overlapped (or arranged) in the first non-display area NDA1. For example, as shown in FIG. 3, the second cathode electrode 117′ may be arranged to extend (or extend) from an end 110a of the substrate 110 in the first non-display area NDA1 to an area between the display area DA and the common power shorting bar EVSB. Accordingly, as shown in FIG. 3, the second cathode electrode 117′ may partially overlap the first cathode electrode 117. According to one example, the second cathode electrode 117′ may partially contact an upper surface of the first cathode electrode 117. Accordingly, the second cathode electrode 117′ may be electrically connected to the first cathode electrode 117, and thus may receive a same common power from the pad portion PA.

The second cathode electrode 117′ may be formed of at least one of an opaque metal material, a transparent metal material, and a semi-transparent metal material. For example, the second cathode electrode 117′ may be formed of an opaque metal material, such as silver (Ag), aluminum (Al), a laminated structure of aluminum and titanium (Ti/Al/Ti), a laminated structure of aluminum and ITO (ITO/Al/ITO), an Ag alloy, and a laminated structure of Ag alloy and ITO (ITO/Ag alloy/ITO). In this case, since the second cathode electrode 117′ has low resistance, a common power drop can be reduced or prevented. As another example, the second cathode electrode 117′ can be formed of a transparent metal material such as ITO or IZO or a semi-transparent metal material. As described above, since the second cathode electrode 117′ is arranged in the first non-display area NDA1, it may not be formed to reflect light emitted from the organic light-emitting layer 116 toward the substrate 110. Accordingly, the display apparatus 100 according to one embodiment of the present disclosure may have the second cathode electrode 117′ formed of at least one of an opaque metal material, a transparent metal material, and a semi-transparent metal material.

In the display apparatus 100 according to one embodiment of the present disclosure, the substrate 110 may include a first area A1, a second area A2, and a third area A3. The first area A1 may be an area where the first cathode electrode 117 is arranged. The second area A2 may be an area where the second cathode electrode 117′ is arranged. The third area A3 may be an area where the first cathode electrode 117 and the second cathode electrode 117′ overlap. For example, the first area A1 may be an area where the first cathode electrode 117 is arranged in a first direction (Y-axis direction). The second area A2 may be an area where the second cathode electrode 117′ is arranged in the first direction (Y-axis direction). The third area A3 may be an area where the first cathode electrode 117 and the second cathode electrode 117′ overlap in the first direction (Y-axis direction). As shown in FIG. 3, the first area A1, the second area A2, and the third area A3 may be arranged in a row in the first direction (Y-axis direction), and the third area A3 may be arranged between the first area A1 and the second area A2 in the first direction (Y-axis direction). A combined length of the first area A1 and the second area A2 in the first direction (Y-axis direction) may be equal to or similar to a length of the substrate 110 in the first direction (Y-axis direction).

Referring again to FIG. 2, the encapsulation layer 118 is formed on the first cathode electrode 117 and/or the second cathode electrode 117′. The encapsulation layer 118 prevents or at least reduces oxygen or moisture from penetrating into the organic light-emitting layer 116, the first cathode electrode 117, and the second cathode electrode 117′. The encapsulation layer 118 may be provided with a plurality of layers including at least one inorganic film and at least one organic film.

Meanwhile, as shown in FIG. 2, the encapsulation layer 118 may be arranged in the light-emission area EA and in the non-light emission area NEA. In FIG. 2, the encapsulation layer 118 may be arranged between the first cathode electrode 117 and the opposing substrate 200. However, in the first non-display area NDA1 where the second cathode electrode 117′ is arranged, the encapsulation layer 118 may be arranged between the second cathode electrode 117′ and the opposing substrate 200.

The filling layer 119 is arranged between the organic light-emitting layer 116 formed on the substrate 110 and the opposing substrate 200, thereby preventing external moisture and/or oxygen penetrating through the opposing substrate 200 from reaching the organic light-emitting layer 116. That is, the filling layer 119 may have a barrier function that prevents moisture penetration. The filling layer 119 may further contain an absorbent material for absorbing moisture or oxygen in order to enhance the moisture-prevention effect. For example, the absorbent material may be a getter.

Meanwhile, the filling layer 119 may include at least one of a pressure-sensitive transparent adhesive and a heat-curable transparent adhesive. In this case, the filling layer 119 may be used to bond the substrate 110 and the opposing substrate 200. Therefore, a bonding strength between the substrate 110 and the opposing substrate 200 may be further improved by the filling layer 119.

Referring to FIG. 3, in the display apparatus 100 according to one embodiment of the present disclosure, the common power shorting bar EVSB may be provided in a bar-type or square shape. For example, the common power shorting bar EVSB may be placed in the second area A2 that does not overlap with the third area A3. The common power shorting bar EVSB may be provided extending along the first side DAL1 of the display area DA in the second area A2. In one example, a length of the common power shorting bar EVSB in the second direction (X-axis direction) may be equal to or similar to a length of the display area DA in the second direction (X-axis direction).

In the case of a general display apparatus, a common power shorting bar is provided in a triangular shape (or squid shape). In the general display apparatus, since the organic light-emitting layer is not arranged to an end of the substrate, the entire common power shorting bar can be used as a contact portion for applying common power to the cathode electrode. Accordingly, in the general display apparatus, since the common power shorting bar is provided in a triangular shape (or squid shape), a contact area between the common power shorting bar and the cathode electrode can be provided widely.

In contrast, the display apparatus 100 according to one embodiment of the present disclosure may be arranged such that the organic light-emitting layer 116 extends from the display area DA to the end of the substrate 110 in the non-display area NDA. That is, the organic light-emitting layer 116 may be provided over the entire display area DA and the non-display area NDA. According to one embodiment of the present disclosure, the display apparatus 100 may contact the common power shorting bar EVSB and the cathode electrode (or the second cathode electrode 117′) through a plurality of undercuts (or a plurality of common power contact undercuts ECUC). Accordingly, if the common power shorting bar is provided in a triangular shape (or a squid shape), a contact area may become small, so that common power application may not be smooth and heat may be generated in the contact area, which may lower reliability.

Therefore, since the display apparatus 100 according to one embodiment of the present disclosure has the common power shorting bar EVSB in a bar-type or square shape, the contact area between the common power shorting bar EVSB and the cathode electrode (or the second cathode electrode 117′) can be increased compared to a case where the common power shorting bar is provided in a triangular shape (or squid shape), so that the common power can be smoothly applied, and heat generation in a contact region where the common power shorting bar EVSB and the cathode electrode (or the second cathode electrode 117′) come into contact can also be reduced, so that reliability can be improved.

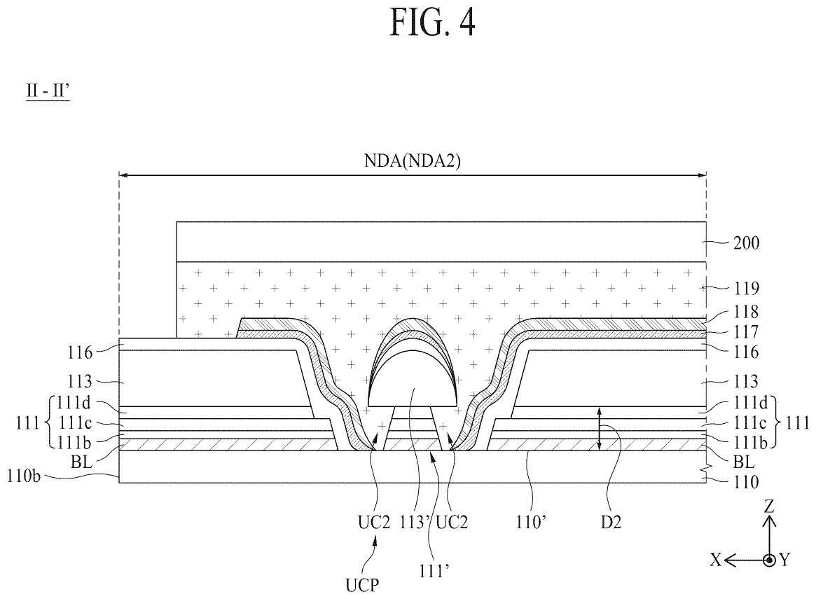

FIG. 4 is a schematic cross-sectional view of the line II-II′ shown in FIG. 3 according to one embodiment of the present disclosure.

Referring to FIG. 4, in the display apparatus 100 according to one embodiment of the present disclosure, the second undercut UC2 may be formed by removing a portion of the plurality of inorganic films 111 and a portion of the planarization layer 113. According to one example, the second undercut UC2 may be formed by partially removing each of the buffer layer BL, the interlayer insulating film 111b, the first passivation layer 111c, the second passivation layer 111d, and the planarization layer 113. Accordingly, as shown in FIG. 4, the plurality of inorganic films 111 may include island inorganic films 111′ that are interrupted by a plurality of second undercuts UC2. Furthermore, the planarization layer 113 may include an island planarization layer 113′ disposed on the island inorganic films 111′.

Meanwhile, the plurality of second undercuts UC2 may be provided on both sides of each of the island inorganic film 111′ and the island planarization layer 113′. For example, as shown in FIG. 4, two second undercuts UC2 may be provided on both sides of each of the island inorganic film 111′ and the island planarization layer 113′. Each of the two second undercuts UC2 provided on both sides of the island inorganic film 111′ and the island planarization layer 113′ may be formed through the same etching process (or pattern process). Therefore, the display apparatus 100 according to one embodiment of the present disclosure may have a structural feature in which the plurality of second undercuts UC2 (or two second undercuts UC2) are provided in a symmetrical shape with respect to the island inorganic film 111′ and the island planarization layer 113′. Due to this, it may also have a structural feature in which a center of the island inorganic film 111′ and a center of the island planarization layer 113′ are arranged in a column in the third direction (Z-axis direction). As shown in FIG. 4, since two second undercuts UC2 are provided on both sides of each of the island inorganic film 111′ and the island planarization layer 113′, it may be expressed in terms of double-sided undercuts or double-sided symmetrical undercuts.

Additionally, as shown in FIG. 4, since the display apparatus 100 according to one embodiment of the present disclosure does not require a mask (or EL mask), the organic light-emitting layer 116 can be arranged to extend to the end 110b of the substrate 110 in the second non-display area NDA2. According to one embodiment of the present disclosure, the display apparatus 100 can prevent or a least reduce moisture penetration through the organic light-emitting layer 116 by allowing the organic light-emitting layer 116 to be disconnected by the second undercut UC2 even if the organic light-emitting layer 116 extends to an end 110b of the substrate 110 in the second non-display area NDA2. In addition, as shown in FIG. 4, in the display apparatus 100 according to one embodiment of the present disclosure, the planarization layer 113 made of an organic material can also be disconnected by the second undercut UC2, so that moisture penetration prevention can be maximized.

Additionally, in the display apparatus 100 according to one embodiment of the present disclosure, since each of a disconnected organic light-emitting layer 116 and a disconnected planarization layer 113 is capped by the first cathode electrode 117 and the encapsulation layer 118, moisture permeation prevention through the organic light-emitting layer 116 and the planarization layer 113 can be further maximized.

Meanwhile, as shown in FIG. 4, the display apparatus 100 according to one embodiment of the present disclosure may have a structural feature in which the organic light-emitting layer 116 and the planarization layer 113 are disconnected by the second undercut UC2, and thus the first cathode electrode 117 formed in a subsequent process comes into contact with an upper surface 110′ of the substrate 110 in the second undercut UC2.

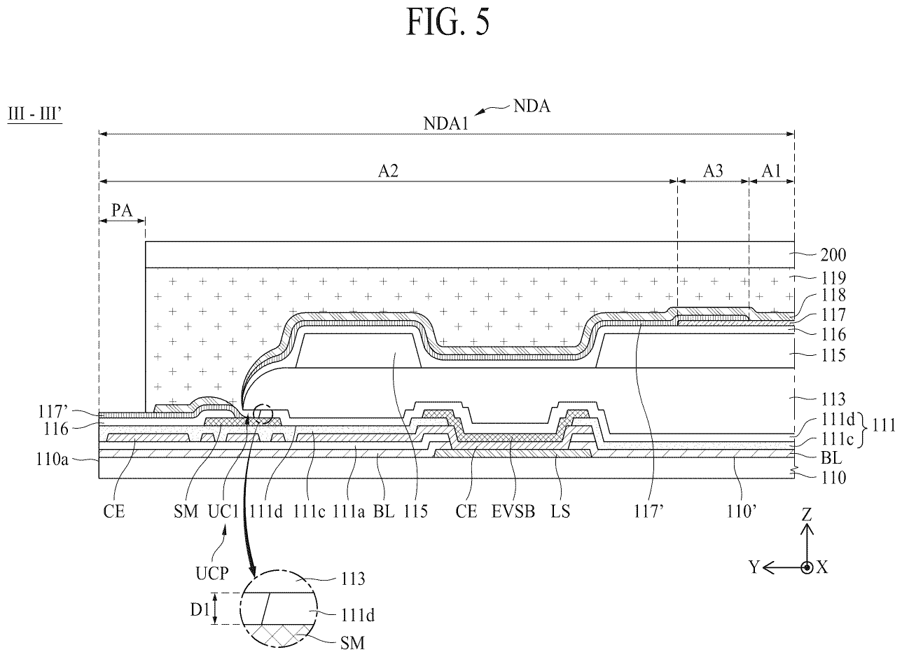

FIG. 5 is a schematic cross-sectional view of the line III-III′ shown in FIG. 3 according to one embodiment of the present disclosure.

Referring to FIG. 5, since the display apparatus 100 according to one embodiment of the present disclosure does not require a mask (or EL mask), the organic light-emitting layer 116 can be arranged to extend to the end 110a of the substrate 110 in the first non-display area NDA1. As shown in FIG. 5, in the display apparatus 100 according to one embodiment of the present disclosure, even if the organic light-emitting layer 116 extends to the end 110a of the substrate 110 in the first non-display area NDA1, the organic light-emitting layer 116 may be disconnected by the first undercut UC1. Accordingly, in the display apparatus 100 according to one embodiment of the present disclosure, since the organic light-emitting layer 116 extending to the first non-display area NDA1 can be disconnected by the first undercut UC1 in the second area A2, moisture penetration through the organic light-emitting layer 116 can be prevented.

According to one example, the first undercut UC1 may be formed by removing a portion of the plurality of inorganic films 111 and a portion of the planarization layer 113 in the second area A2. For example, the first undercut UC1 may be formed by removing a portion of the second passivation layer 111d among the plurality of inorganic films 111 and a portion of the planarization layer 113. Accordingly, the organic light-emitting layer 116 extending to the first non-display area NDA1 may be disconnected by the first undercut UC1.

Meanwhile, since the first non-display area NDA1 is provided with a pad portion PA (or tab bonding portion TBP (shown in FIG. 3)) to which a tab is bonded, the planarization layer 113 at an outer edge of the first non-display area NDA1 (or an area where the pad portion PA is provided) can be removed through an etching process (or pattern process). Accordingly, as shown in FIG. 5, the planarization layer 113 may not be provided on the left side with respect to the first undercut UC1 and may be provided only on the right side. Therefore, the display apparatus 100 according to one embodiment of the present disclosure may have a structural feature in which both sides are provided asymmetrically with respect to the first undercut UC1.

As a result, in the display apparatus 100 according to one embodiment of the present disclosure, the second undercut UC2 is provided symmetrically with respect to the island inorganic film 111′ and the island planarization layer 113′, and a left structure and a right structure are provided asymmetrically with respect to the first undercut UC1, so that the second undercut UC2 and the first undercut UC1 can be provided with different structures. That is, in the display apparatus 100 according to one embodiment of the present disclosure, the second undercut UC2 can be provided to have a different shape from the first undercut UC1.

Meanwhile, since the pad portion PA is not provided in each of the third non-display area NDA3 and the fourth non-display area NDA4, the third undercut UC3 in the third non-display area NDA3 and the fourth undercut UC4 in the fourth non-display area NDA4 may be provided to have the same shape as the second undercut UC2. Accordingly, the third undercut UC3 and the fourth undercut UC4 may be provided symmetrically with respect to the island inorganic film 111′ and the island planarization layer 113′, like the second undercut UC2. Therefore, the organic light-emitting layer 116 extended to an end 110c of the substrate 110 in the third non-display area NDA3 can be disconnected by the third undercut UC3. Furthermore, the organic light-emitting layer 116 extended to an end 110d of the substrate 110 in the fourth non-display area NDA4 can be disconnected by the fourth undercut UC4.

As a result, in the display apparatus 100 according to one embodiment of the present disclosure, the first undercut UC1, the second undercut UC2, the third undercut UC3, and the fourth undercut UC4 are arranged to surround the display area DA, so that even if the organic light-emitting layer 116 is arranged to extend from the display area DA to the end of the substrate 110, moisture and oxygen permeation (or infiltration) through the organic light-emitting layer 116 can be prevented by the first undercut UC1, the second undercut UC2, the third undercut UC3, and the fourth undercut UC4. Therefore, the display apparatus 100 according to one embodiment of the present disclosure can have improved reliability, and thus, its lifespan can be improved.

Referring to FIG. 5, the common power shorting bar EVSB arranged in the second area A2 can be electrically connected to a LS layer LS and a connection electrode CE sequentially stacked on the upper surface of the substrate 110. The LS layer LS is connected to the pad portion PA and can apply common power applied from the pad portion PA to the connection electrode CE. The connection electrode CE can apply common power applied from the LS layer LS to the common power shorting bar EVSB. Therefore, the common power shorting bar EVSB can receive common power from the pad portion PA.

Referring to FIG. 5, in the display apparatus 100 according to one embodiment of the present disclosure, the second cathode electrode 117′ may partially contact an upper surface of the first cathode electrode 117 in the third area A3. Accordingly, the second cathode electrode 117′ may be electrically connected to the first cathode electrode 117. Meanwhile, the first undercut UC1 may be formed by removing a portion of the second passivation layer 111d. In contrast, the second undercut UC2 may be formed by partially removing each of the buffer layer BL, the interlayer insulating film 111b, the first passivation layer 111c, the second passivation layer 111d, and the planarization layer 113. Accordingly, a depth D1 of the first undercut UC1 may be smaller than a depth D2 of the second undercut UC2. As shown in FIG. 5, in the first undercut UC1, the second cathode electrode 117′ may be in contact with a stopper metal SM. The stopper metal SM may be an etching prevention film to prevent the first passivation layer 111c from being etched. According to one example, the stopper metal SM may be provided on the same layer as the common power shorting bar EVSB and may be provided with the same material.

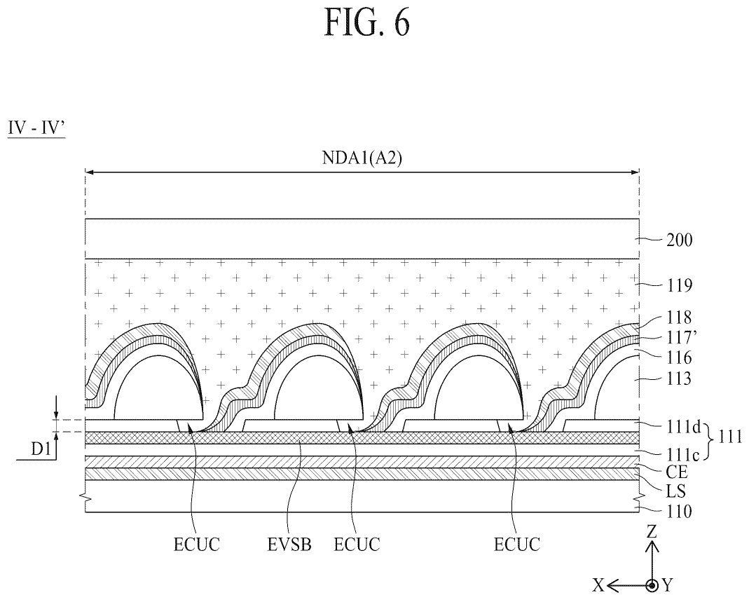

FIG. 6 is a schematic cross-sectional view of the line IV-IV′ shown in FIG. 3 according to one embodiment of the present disclosure.

Referring to FIG. 6, the display apparatus 100 according to one embodiment of the present disclosure may further include a plurality of common power contact undercuts ECUC. Each of the plurality of common power contact undercuts ECUC is for disconnecting the organic light-emitting layer 116 so that the common power shorting bar EVSB and the cathode electrode (or the second cathode electrode 117′) are connected.

Since the display apparatus 100 according to one embodiment of the present disclosure does not require a mask (or EL mask), the organic light-emitting layer 116 may be arranged to extend to the end 110a of the substrate 110 in the first non-display area NDA1. Accordingly, in order for the cathode electrode (or the second cathode electrode 117′) to receive common power from the common power shorting bar EVSB, the organic light-emitting layer 116 arranged on the common power shorting bar EVSB must be disconnected.

In the display apparatus 100 according to one embodiment of the present disclosure, each of the plurality of common power contact undercuts ECUC may disconnect an organic light-emitting layer 116 disposed on a common power shorting bar EVSB. For example, each of the plurality of common power contact undercuts ECUC may be formed by partially removing the second passivation layer 111d provided on the common power shorting bar EVSB (or the second area A2) and the planarization layer 113 provided on the second passivation layer 111d.

In the second area A2, after the plurality of common power contact undercuts ECUC are formed, the organic light-emitting layer 116, the second cathode electrode 117′, and the encapsulation layer 118′can be sequentially formed. Accordingly, as illustrated in FIG. 6, the organic light-emitting layer 116 on the common power shorting bar EVSB can be disconnected by each of the plurality of common power contact undercuts ECUC. Furthermore, the second cathode electrode 117′ can be in contact with the common power shorting bar EVSB in the each of the plurality of common power contact undercuts ECUC. Therefore, the display apparatus 100 according to one embodiment of the present disclosure can smoothly receive common power from the common power shorting bar EVSB by having the second cathode electrode 117′ contact the common power shorting bar EVSB in the each of the plurality of common power contact undercuts ECUC, thereby increasing a contact area. As described above, since the second cathode electrode 117′ is electrically connected to the first cathode electrode 117 in the third area A3, the common power applied to the second cathode electrode 117′ can be applied to the first cathode electrode 117.

Meanwhile, since each of the plurality of common power contact undercuts ECUC is formed by partially removing each of the second passivation layer 111d and the planarization layer 113, a depth D1 (or a first depth D1) of each of the common power contact undercuts ECUC may be the same as the depth D1 (or the first depth D1) of the first undercut UC1 illustrated in FIG. 5.

Since the depth D1 (or the first depth D1) of the first undercut UC1 is smaller than a depth D2 (or a second depth D2) of the second undercut UC2, the depth D1 (or the first depth D1) of each of the common power contact undercuts ECUC may also be smaller than the depth D2 (or the second depth D1) of the second undercut UC2. Since the depth D1 (or the first depth D1) of each of the common power contact undercuts ECUC is smaller than the depth D2 (or the second depth D2) of the second undercut UC2, it may be difficult for the second cathode electrode 117′ to contact the common power shorting bar EVSB in the each of the common power contact undercuts ECUC. Therefore, in the display apparatus 100 according to one embodiment of the present disclosure, the first cathode electrode 117 provided in the second undercut UC2 may be formed by a chemical vapor deposition process, and the second cathode electrode 117′ provided in the common power contact undercut ECUC (or the first undercut UC1) may be formed by a sputtering process.

The chemical vapor deposition process according to one example is a process of depositing a material forming the second cathode electrode 117′ on the substrate 110 through a chemical reaction such as thermal decomposition, photodecomposition, or redox reaction. In contrast, the sputtering process is a process of accelerating a gas such as ionized argon in a low vacuum and colliding it with the material forming the second cathode electrode 117′ to form a film on the substrate 110. Therefore, the sputtering process may be more suitable for a shallow (or low) undercut than the chemical vapor deposition process.

Therefore, the display apparatus 100 according to one embodiment of the present disclosure may have a process characteristic in which a first cathode electrode 117 provided in a second undercut UC2 having the second depth D2 is formed by the chemical vapor deposition process, and a second cathode electrode 117′ provided in the common power contact undercut ECUC (or the first undercut UC1) having the first depth D1 is formed by the sputtering process.

Due to the process characteristics as described above, when a foreign substance is located on the display area DA (or above the pixel electrode 114), a material (e.g., Al) forming the first cathode electrode 117 cannot penetrate deep under the foreign substance by the chemical vapor deposition process, so that a short between the pixel electrode 114 and the first cathode electrode 117 can be prevented. In contrast, a material (e.g., IZO) forming the second cathode electrode 117′ can be deeply penetrated into the common power contact undercut ECUC by the sputtering process, so that cathode contact failure in the common power shorting bar EVSB can be prevented.

As a result, in the display apparatus 100 according to one embodiment of the present disclosure, since the cathode electrode (or the first cathode electrode 117) provided in the display area DA is formed through a chemical vapor deposition process, dark spot defects in the display area DA can be improved or prevented.

In addition, since the cathode electrode (or the second cathode electrode 117′) provided on the common power shorting bar EVSB of the display apparatus 100 according to one embodiment of the present disclosure is formed through the sputtering process, cathode contact failure in the common power shorting bar EVSB can be prevented.

Meanwhile, as shown in FIG. 6, the second cathode electrode 117′ that contacts the common power shorting bar EVSB in the common power contact undercut ECUC has the role of applying common power to the display area DA, and therefore can be expressed in terms of a cathode electrode for applying common power.

Referring to FIG. 6, in the display apparatus 100 according to one embodiment of the present disclosure, each of the plurality of common power contact undercuts ECUC may be provided only on one side of the second passivation layer 111d. For example, each of the plurality of common power contact undercuts ECUC may be provided only on a right side of the second passivation layer 111d based on FIG. 6. When the common power contact undercut ECUC is provided as a double-sided undercut like the second undercut UC2, the distance between the planarization layers 113 becomes short, making it difficult for a material forming the second cathode electrode 117′ to penetrate into the common power contact undercut ECUC.

Therefore, the display apparatus 100 according to one embodiment of the present disclosure can secure a sufficient distance between the planarization layers 113 by providing each of the plurality of common power contact undercuts ECUC on only one side of the second passivation layer 111d, thereby allowing a material forming the second cathode electrode 117′ to penetrate deeply into the common power contact undercut ECUC. Therefore, in the display apparatus 100 according to one embodiment of the present disclosure, contact failure between the second cathode electrode 117′ and the common power shorting bar EVSB can be prevented in the plurality of common power contact undercuts ECUC.

As shown in FIG. 6, the common power contact undercut ECUC is provided only on a lower side of one side of the planarization layer 113, and thus can be expressed in terms of a one-sided undercut or a common power one-sided undercut.

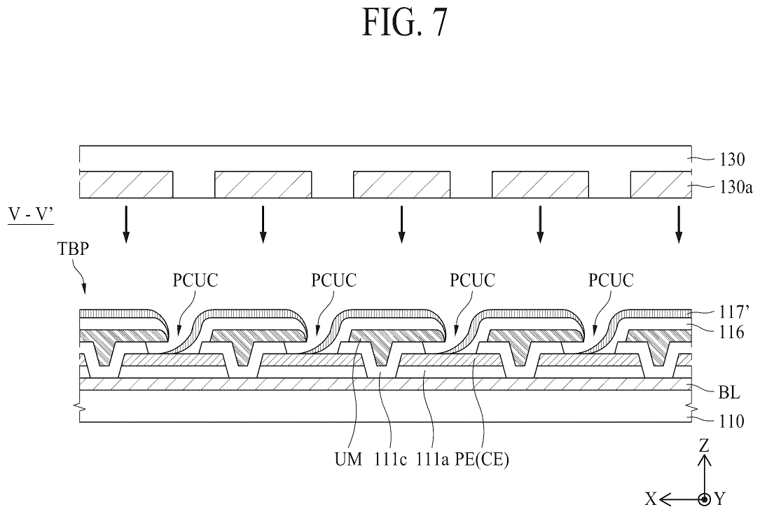

FIG. 7 is a schematic cross-sectional view of the line V-V′ shown in FIG. 3 according to one embodiment of the present disclosure. Specifically, FIG. 7 is a drawing including a schematic cross-sectional view of line V-V′ illustrated in FIG. 3 and is a drawing schematically showing an attachment process of a tab bonding portion TBP and a plurality of tabs 130a.

Referring to FIG. 7, the display apparatus 100 according to one embodiment of the present disclosure may further include a plurality of tab bonding portions TBP.

The plurality of tab bonding portions TBP are provided for attaching a plurality of tabs 130a provided on the flexible film 130. According to one example, a plurality of tab bonding portions TBP may be provided in the first non-display area NDA1. As shown in FIG. 3, each of the plurality of tab bonding portions TBP may include a plurality of pad portion contact undercuts PCUC in which the organic light-emitting layer 116 is disconnected.

Each of the plurality of pad portion contact undercuts PCUC may be connected to the first undercut UC1. For example, as shown in FIG. 3, the plurality of pad portion contact undercuts PCUC may be connected to the first undercut UC1 arranged to extend in the second direction (X-axis direction). Each of the plurality of pad portion contact undercuts PCUC may be arranged to extend in the first direction (Y-axis direction). Accordingly, the organic light-emitting layer 116 in the first non-display area NDA1 can be disconnected by the first undercut UC1 arranged to extend in the second direction (X-axis direction). Furthermore, the organic light-emitting layer 116 in the plurality of tab bonding portions TBP can be disconnected by the plurality of pad portion contact undercuts PCUC arranged to extend in the first direction (Y-axis direction). Therefore, in the display apparatus 100 according to one embodiment of the present disclosure, the first non-display area NDA1, which may be relatively vulnerable to moisture penetration due to the pad portion PA, can be more effectively prevented from moisture penetration due to a connection structure of the first undercut UC1 and the plurality of pad portion contact undercuts PCUC.

Referring to FIG. 7, each of the plurality of tab bonding portions TBP according to one example may include a gate insulating layer 111a, a pad electrode PE, a first passivation layer 111c, and an undercut metal UM. The gate insulating layer 111a may be provided on the substrate 110. The pad electrode PE may be provided on the gate insulating layer 111a. The pad electrode PE according to one example may be provided on the same layer as the connection electrode CE of FIG. 5 and may be provided with the same material as the connection electrode CE of FIG. 5. The first passivation layer 111c may be provided on the pad electrode PE. For example, one first passivation layer 111c may be provided so as to partially contact each of two pad electrodes PE spaced apart from each other.

The undercut metal UM may be provided on the first passivation layer 111c. According to one example, the undercut metal UM may be formed on the same layer as the common power shorting bar EVSB and may be provided with the same material as the common power shorting bar EVSB. For example, the undercut metal UM may be provided with a metal material. Since the undercut metal UM is provided as a metal material, deformation caused by heat generated during an ACF bonding process for bonding the plurality of tabs 130a and the second cathode electrode 117′ can be minimized or at least reduced. The ACF bonding process may refer to a process for bonding two materials using heat.

Referring again to FIG. 7, the undercut metal UM is for forming the pad portion contact undercut PCUC. For example, by providing the undercut metal UM to protrude toward one side of the first passivation layer 111c, the pad portion contact undercut PCUC can be formed under the undercut metal UM. Accordingly, as shown in FIG. 7, each of the plurality of pad portion contact undercuts PCUC may be provided on a lower side of one side of the undercut metal UM. For example, each of the plurality of pad portion contact undercuts PCUC may be provided on a lower side of a right side of the undercut metal UM based on FIG. 7.

When the pad portion contact undercut PCUC is provided as a double-sided undercut like the second undercut UC2, the distance between the undercut metals UM becomes short, making it difficult for a material forming the second cathode electrode 117′ to penetrate into the pad portion contact undercut PCUC.

Therefore, the display apparatus 100 according to one embodiment of the present disclosure can secure a sufficient distance between the undercut metals UM by providing each of the plurality of pad portion contact undercuts PCUC only on one side of the first passivation layer 111c, so that a material forming the second cathode electrode 117′ can penetrate deeply into the pad portion contact undercut PCUC, thereby preventing a contact failure between the second cathode electrode 117′ and the pad electrode PE.

As shown in FIG. 7, each of the plurality of pad portion contact undercuts PCUC is provided only on one lower side of one side of the undercut metal UM, and thus can be expressed in terms of a one-sided undercut or a pad one-sided undercut.

Meanwhile, the second cathode electrode 117′ that contacts with the pad electrode PE in the pad portion contact undercut PCUC has the role of applying data power, reference power, pixel power, and common power applied from the pad PA to the display area DA, and therefore can be expressed in terms of a cathode electrode for applying pad power or a cathode electrode for applying pad portion signal.

Referring to FIG. 7, the plurality of pad portion contact undercuts PCUC are provided on each of the plurality of tab bonding portions TBP, so that the organic light-emitting layer 116 can be disconnected at each of the plurality of pad portion contact undercuts PCUC. In addition, the second cathode electrode 117′ can be brought into contact with the pad electrode PE in the each of the plurality of pad portion contact undercuts PCUC. Accordingly, since the second cathode electrode 117′ and the pad electrode PE are in contact in the tab bonding portion TBP, the second cathode electrode 117′ can be provided as an electrode integrated with the pad electrode PE. Therefore, in the display apparatus 100 according to one embodiment of the present disclosure, each of the plurality of tabs 130a provided on the flexible film 130 can be easily bonded to each of the plurality of tab bonding portions TBP.

As shown in FIG. 7, the organic light-emitting layer 116 and the second cathode electrode 117′ can be sequentially laminated on the undercut metal UM in each of the plurality of tab bonding portions TBP. Since the organic light-emitting layer 116 is provided on the undercut metal UM that is provided flatly, it can be provided flatly. In addition, since the second cathode electrode 117′ is provided on the organic light-emitting layer 116 that is provided flatly, the second cathode electrode 117′ can also be provided flatly. As a result, the second cathode electrode 117′ laminated on the undercut metal UM can be provided flatly.

According to one embodiment of the present disclosure, the display apparatus 100 may have the second cathode electrode 117′laminated on the undercut metal UM so as to be flat. Accordingly, according to one embodiment of the present disclosure, the display apparatus 100 may have a tab 130a having a flat lower surface more easily attached to the second cathode electrode 117′. In addition, in the display apparatus 100 according to one embodiment of the present disclosure, a contact area can be widened compared to when the second cathode electrode is provided in a rough shape, so that power and/or signals of the pad portion PA can be easily applied to the second cathode electrode 117′.

As a result, the display apparatus 100 according to one embodiment of the present disclosure can block moisture penetration through the organic light-emitting layer 116 by applying an undercut structure to each of the non-display area NDA, an area provided with the common power shorting bar EVSB, and an area provided with the tab bonding portion TBP. And, the display apparatus 100 according to one embodiment of the present disclosure may have a structural feature in which the organic light-emitting layer 116 is disconnected by an undercut structure in each of an area where the common power shorting bar EVSB is provided and an area where the tab bonding portion TBP is provided, so that the cathode electrode (or the second cathode electrode 117′) and the common power shorting bar EVSB may be contact in the area where the common power shorting bar EVSB is provided, and the cathode electrode (or the second cathode electrode 117′) and the plurality of tabs 130a may be contact in the area where the tab bonding portion TBP is provided.

Embodiments of the present disclosure have been described in more detail with reference to the accompanying drawings, but the present disclosure is not necessarily limited to these embodiments and may be implemented in various modifications without departing from the technical ideas of the present disclosure. Accordingly, the embodiments disclosed herein are intended to illustrate and not to limit the technical ideas of the present disclosure, and the scope of the technical ideas of the present disclosure is not limited by these embodiments. Therefore, the embodiments described above are exemplary in all respects and should be understood as non-limiting. The scope of protection of this disclosure shall be construed by the claims, and all technical ideas within the scope of the claims shall be construed to be included within the scope of the claims.

The present disclosure may be arranged so that the organic light-emitting layer extends from the display area to the end of the substrate. Accordingly, even if the present disclosure is manufactured in various sizes, masks (or EL masks) of various sizes are not required, so the manufacturing cost can be reduced.

Furthermore, the present disclosure can be manufactured in various sizes without masks (or EL masks) of various sizes. Therefore, the present disclosure may optimize a process compared to display apparatuses manufactured using masks (or EL masks) of various sizes, so that production energy can be reduced.

Furthermore, the present disclosure can reduce or prevent moisture penetration by arranging an undercut portion where the organic light-emitting layer is disconnected around the display area.

Furthermore, in the present disclosure, a cathode electrode (or a first cathode electrode) provided in a display area can be formed through a chemical vapor deposition process. Accordingly, in the present disclosure, a dark spot defect in the display area can be improved or prevented.

Furthermore, the present disclosure provides that a cathode electrode (or a second cathode electrode) provided in a common power shorting bar can be formed through a sputtering process. Accordingly, the present disclosure can prevent cathode contact failure in the common power shorting bar.

The effects that may be obtained from the present disclosure are not limited to those mentioned above, and other effects not mentioned will be apparent to one having ordinary skill in the art from the following description.

What is claimed is:

1. A display apparatus comprising:
a substrate having a display area in which a plurality of pixels having a plurality of sub-pixels are arranged and a non-display area around the display area; and
an organic light-emitting layer on the substrate, each of the plurality of sub-pixels having the organic light-emitting layer,
wherein the organic light-emitting layer extends from the display area to an end of the substrate,
wherein the substrate includes an undercut portion in which the organic light-emitting layer is disconnected, and
wherein the undercut portion is in the non-display area and surrounds the display area.

2. The display apparatus of claim 1, wherein the non-display area includes:
a first non-display area having a pad portion, the first non-display area adjacent to a first side of the display area; and
a second non-display area connected to the first non-display area, the second non-display area adjacent to a second side of the display area; and
wherein the undercut portion includes:
a first undercut in the first non-display area; and
a second undercut in the second non-display area.

3. The display apparatus of claim 2, wherein the second undercut has a different shape from the first undercut.

4. The display apparatus of claim 2, wherein the non-display area includes:
a third non-display area that is spaced apart from the second non-display area with the display area therebetween; and
a fourth non-display area that is spaced apart from the first non-display area with the display area therebetween,
wherein the undercut portion further includes:
a third undercut in the third non-display area; and
a fourth undercut in the fourth non-display area,
wherein the third undercut and the fourth undercut have a same shape as the second undercut.

5. The display apparatus of claim 2, wherein the substrate includes:
a first cathode electrode on the organic light-emitting layer, the first cathode electrode overlapping the display area and a portion of the first non-display area; and
a second cathode electrode partially contacting an upper surface of the first cathode electrode, the second cathode electrode in the first non-display area.

6. The display apparatus of claim 5, wherein the first cathode electrode is formed by a chemical vapor deposition process and the second cathode electrode is formed by a sputtering process.

7. The display apparatus of claim 5, wherein the first cathode electrode includes an opaque metal material and the second cathode electrode includes at least one of an opaque metal material, a transparent metal material, or a semi-transparent metal material.

8. The display apparatus of claim 5, wherein the substrate includes:
a first area in which the first cathode electrode is arranged;
a second area in which the second cathode electrode is arranged; and
a third area in which the first cathode electrode and the second cathode electrode overlap,
wherein the third area is between the first area and the second area.

9. The display apparatus of claim 8, wherein the substrate further includes a common power shorting bar in the second area, and the common power shorting bar is a bar-type or square-shaped.

10. The display apparatus of claim 2, further comprising:
a plurality of inorganic films between the substrate and the organic light-emitting layer; and
a planarization layer between the plurality of inorganic films and the organic light-emitting layer,
wherein the second undercut is formed by removing a portion of the plurality of inorganic films and a portion of the planarization layer.

11. The display apparatus of claim 10, wherein the plurality of inorganic films include an island inorganic film that is disconnected by a plurality of second undercuts,
wherein the planarization layer includes an island planarization layer on the island inorganic film, and
wherein the plurality of second undercuts have a symmetrical shape based on the island inorganic film and the island planarization layer.

12. The display apparatus of claim 8, wherein the organic light-emitting layer extends from the display area to an end of the substrate having the first non-display area, and
wherein the organic light-emitting layer extending to the first non-display area is disconnected by the first undercut in the second area.

13. The display apparatus of claim 9, wherein a plurality of common power contact undercuts are on the common power shorting bar,
wherein the organic light-emitting layer is disconnected by each of the plurality of common power contact undercuts, and
wherein the second cathode electrode is in contact with the common power shorting bar in each of the plurality of common power contact undercuts.

14. The display apparatus of claim 13, wherein each of the plurality of common power contact undercuts is formed by partially removing each of a passivation layer provided on the common power shorting bar and a planarization layer provided on the passivation layer.

15. The display apparatus of claim 14, wherein each of the plurality of common power contact undercuts is on one side of the passivation layer.

16. The display apparatus of claim 5, wherein the substrate includes a plurality of tab bonding portions in the first non-display area, and each of the plurality of tab bonding portions includes a plurality of pad portion contact undercuts in which the organic light-emitting layer is disconnected.

17. The display apparatus of claim 16, wherein each of the plurality of pad portion contact undercuts is connected to the first undercut.

18. The display apparatus of claim 16, wherein each of the plurality of tab bonding portions includes:
a gate insulating layer on the substrate;
a pad electrode on the gate insulating layer;
a passivation layer on the pad electrode; and
an undercut metal on the passivation layer, and
wherein each of the plurality of pad portion contact undercuts is on a lower side of one side of the undercut metal.

19. The display apparatus of claim 18, wherein the second cathode electrode is in contact with the pad electrode in each of the plurality of pad portion contact undercuts.

20. The display apparatus of claim 18, wherein the organic light-emitting layer and the second cathode electrode are sequentially laminated on the undercut metal, and the second cathode electrode laminated on the undercut metal is provided flatly.
